(19) United States
(12) Patent Application Publication
(10) Pub. No.: US 2004/0238876 A1
(43) Pub. Date: Dec. 2, 2004

(54) Semiconductor structure having low resistance and method of manufacturing same

(76) Inventors: Sunpil Youn, Seoul (KR); Seong-Jun Heo, Seoul (KR); Sung-Man Kim, Seoul (KR); Chang-Won Lee, Seoul (KR); Ja-Hum Ku, Kyunggi-Do (KR); Siyoung Choi, Kyunggi-Do (KR)

Correspondence Address: MARGER JOHNSON & McCOLLOM, P.C., 1030 S.W. Morrison Street, Portland, OR, 97205, US

(21) Appl. No.: 10/448,534

(22) Filed: May 29, 2003

(51) Int. Cl. H01L 29/788

(52) U.S. Cl. 257/315

(57) ABSTRACT

Embodiments of the present invention include semiconductor devices that can be made with relatively low resistance, and methods of forming such devices. Between forming a polysilicon layer and a metal layer, an interface reaction preventing layer is created. This reaction preventing layer prevents a buildup of highly resistive materials that would otherwise occur when creating conventional semiconductor devices, as well as having other functions.

### TECHNICAL FIELD

This disclosure relates to a semiconductor device having a low resistance metal-polysilicon gate electrode and a method of manufacturing the same.

### BACKGROUND

The trend in integrated semiconductor devices has and continues to be toward increased packing density, higher operating frequencies, and lower operating voltages. As these trends continue, the feature size of patterns formed on a chip and the space between the formed patterns are becoming smaller. In the past, polysilicon was a very useful material for forming and interconnecting individual components, such as for forming gate electrodes. However, as the pattern size decreases, resistance of interconnections becomes increasingly important. Because polysilicon has a relatively high resistivity, as the pattern size continues to decrease, polysilicon interconnections have a relatively higher RC (resistive-capacitive) time delay and IR (current-resistance) voltage drop than in the older circuits having larger pattern sizes.

Therefore, polycide structures, which have similar characteristics to those of polysilicon while having a lower resistivity than polysilicon, have become increasingly popular. One method of using a polycide structure is to have a multilayer structure consisting of a refractory metal silicide, such as titanium silicide or tungsten silicide on a doped polysilicon layer. Such a structure has been used to interconnect and form components, such as gate electrodes of VLSI circuits. However, the resistivity of the tungsten silicide is approximately 100 μΩ-cm, which is still relatively high, and further reduction in the resistivity of the gate electrode is required to form acceptable sub-quarter-micron ultra-large scale integrated (ULSI) circuits.

Thus the industry has recently turned to tungsten-polysilicon (hereinafter, referred to as “W-poly”) gate structures, because a W-poly gate structure has a resistivity of approximately 10 μΩcm, which is lower than the conventional polysilicon or polycide gate electrodes.

FIG. 1 is a cross-sectional diagram of a conventional MOS transistor having a W-poly gate structure. A gate dielectric layer 12 is formed on a silicon substrate 10. A gate stack 20, which includes a doped polysilicon layer 14, a barrier layer 16 and a tungsten (W) layer 18, is formed on the gate dielectric layer 12. A gate capping layer 22 of silicon nitride (SiN) is formed on the gate stack 20. Because tungsten reacts with silicon (Si) at a temperature as low as 600° C. in a process known as silicidation, it is necessary to form a high quality diffusion barrier layer 16 between the W layer 18 and the polysilicon layer 14 to prevent such silicidation. Titanium nitride (TiN) and tungsten nitride (WN) and are both candidates for the diffusion barrier 16 to avoid silicidation of the W layer 18.

In a conventional post-gate etching process, dry or wet oxidation (i.e., selective oxidation) is used to cure the etch damage and to improve the gate dielectric strength. Thus, all gate materials, including the metal materials (W and the barrier material) are subjected to this oxidation. Under selective oxidation conditions, the W-based materials will not be oxidized. However, if the barrier layer 16 is TiN, the TiN layer can oxidize, which can result in lift-off of the W layer 18. Accordingly, from a point of a low resistivity and process integration, the W-poly gate electrode without TiN is preferred.

There are also problems with using WN as the barrier layer 16. When the barrier layer 16 is formed of WN, nitrogen (N₂) flows into the polysilicon layer 14 during the deposition of the WN barrier layer 16. This causes nitrogen to react with the polysilicon layer 14 to form a high resistance SiN-based insulation layer between the WN barrier layer 16 and the polysilicon layer 14. Further, during the selective oxidation process, oxidants diffuse into the interface between the WN barrier layer 16 and the polysilicon layer 14 to thereby form an insulating layer, such as a silicon oxynitride layer. This causes even more resistance, which in turn increases the contact resistance (Rc) between the W layer 18 and the polysilicon layer 14.

As mentioned above, increased resistance is to be avoided, because increased resistance causes a higher RC delay, which in turn causes tRCD (Ras to CAS Delay Time) failure in memory devices, thereby deteriorating the yield and the operating speed of the end component.

Embodiments of the invention address this and other limitations in the prior art.

### BRIEF DESCRIPTION OF THE DRAWINGS

The invention will be understood more fully from the detailed description given below and from the accompanying drawings of embodiments of the invention, which, however, should not be taken to limit the invention to the specific embodiments, but are to facilitate explanation and understanding.

FIG. 1 is a cross-sectional diagram illustrating a conventional MOS transistor having a W-poly gate structure.

FIG. 2 is a cross-sectional diagram of a MOS transistor having a metal-polysilicon gate structure according to an embodiment of the present invention.

FIGS. 3A, 3B, 3C, and 3D are cross-sectional diagrams illustrating methods of manufacturing the MOS transistor shown in FIG. 2, according to embodiments of the invention.

FIG. 4 is a cross-sectional diagram illustrating a W-poly metal contact structure according to another embodiment of the invention.

FIG. 5 is a graph comparing contact resistances of conventional W-poly contact structures to W-poly contact structures according to embodiments of the present invention.

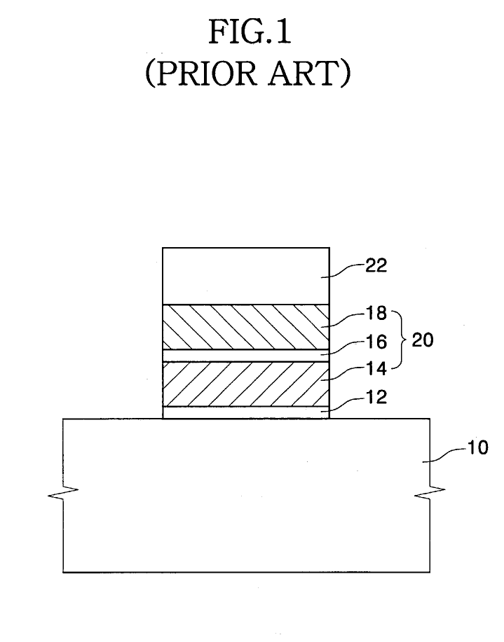

### DETAILED DESCRIPTION

In the following detailed descriptions, numerous specific details are set forth in order to provide a thorough understanding of the invention. However, it will be understood by those skilled in the art that the present invention may be practiced without these specific details. In other instances, well-known methods, procedures, components and processes have not been described in detail so as not to obscure the explanation of the present invention.

Embodiments of the invention are directed toward a MOS transistor having a gate stack with low resistance, and methods of forming such a transistor. This low resistance is obtained by preventing the formation of highly resistive materials that typically occur when creating the gate stack using conventional methods.

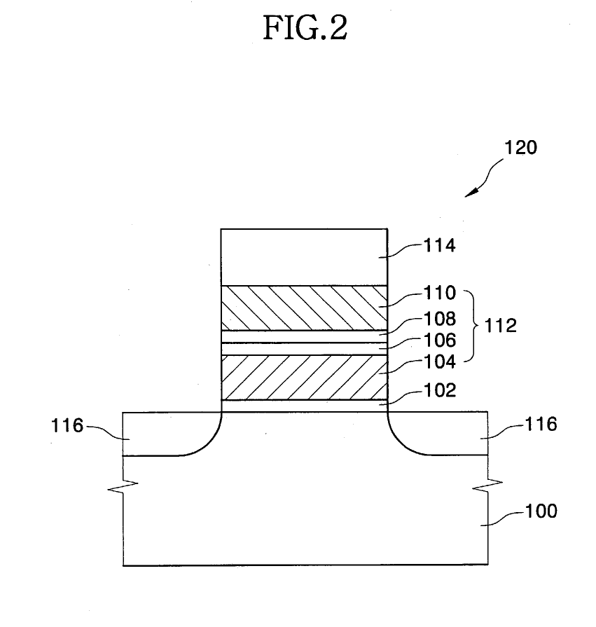

FIG. 2 is a cross-sectional diagram of a MOS transistor having a metal-polysilicon gate structure in accordance with an embodiment of the present invention. Referring to FIG. 2, a transistor 120 is formed on a semiconductor substrate 100 and is isolated from other electrical elements (not shown) by field regions (also not shown). The transistor 120 has active source/drain regions 116 and a gate stack 112.

A gate dielectric layer 102 separates the gate stack 112 and the substrate 100. The gate stack 112 illustrated in FIG. 2 includes a doped polysilicon layer 104 formed on the gate dielectric layer 102, an interface-reaction preventing layer 106 formed on the polysilicon layer 104, a barrier layer 108 formed on the interface-reaction preventing layer 106, and a metal layer 110 formed on the barrier layer 108. A gate capping layer 114 formed of, for example, silicon nitride (SiN) may be formed at the top of the gate stack 112. The gate capping layer 114 prevents an oxidation of the metal layer 110 during any subsequent high temperature annealing processing.

The barrier layer 108 is formed of a metal-nitride such as tungsten-nitride (WN), and prevents a reaction between the polysilicon layer 104 and the metal layer 110. The reaction between the polysilicon layer 104 and the metal layer 110 unacceptably increases the sheet resistance of the gate structure 112. Preferably, the metal used in the metal-nitride of the barrier layer 108 is the same material as in the metal layer 110. One such suitable metal is tungsten (W); however other metals may alternatively be used.

The interface-reaction preventing layer 106 is formed of a metal silicide such as tungsten silicide (WSix), which suppresses the formation of a high resistance insulating layer such as silicon nitride during the deposition of the metal-nitride barrier layer 108. Further, the interface-reaction preventing layer 106 prevents oxidants from diffusing to the interface between the metal-nitride barrier layer 108 and the polysilicon layer 104 during a subsequent selective oxidation process for curing etching damages on the gate dielectric layer 102 and the substrate 100. This prevents the formation of an insulating layer of, for example, SiON (silicon oxynitide) that may be formed by a reaction between nitrogen in the barrier layer 108, silicon atoms in the polysilicon layer 104 and the diffused oxidant.

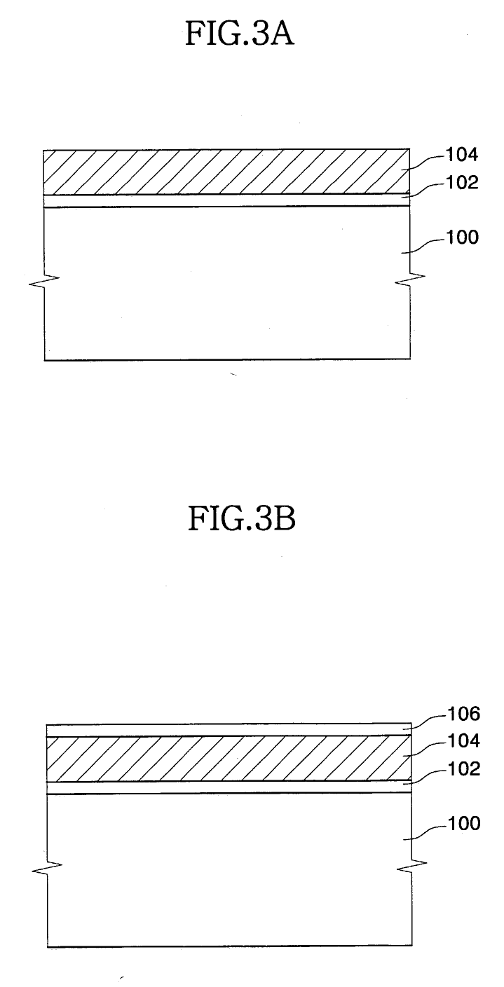

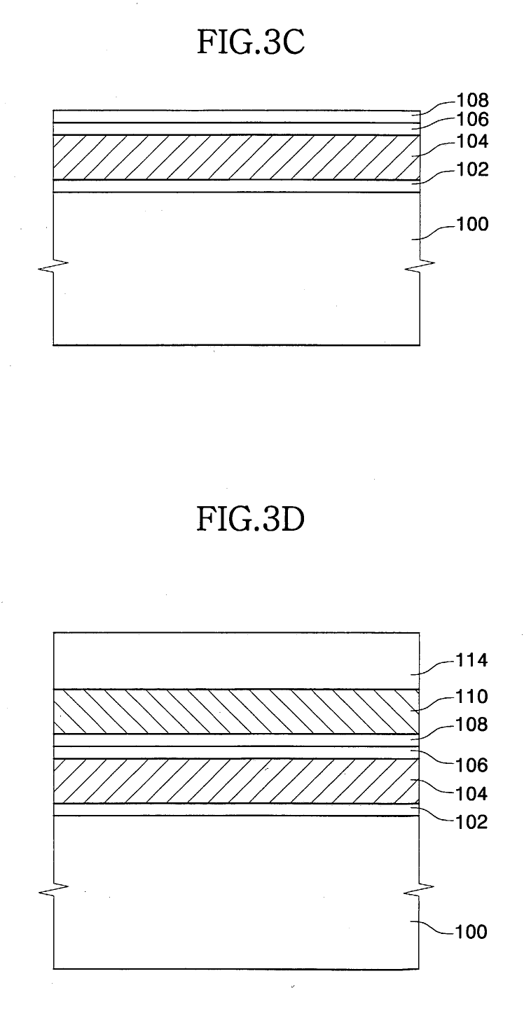

A method for forming the metal-polysilicon gate stack 112 will now be described with reference to FIGS. 3A to 3D. Referring to FIG. 3A, a gate dielectric layer 102 is formed to a thickness of about 50˜60 Å on a semiconductor substrate 100. One way to form the gate dielectric layer is by thermal oxidation. The gate dielectric layer 102 may include silicon oxide (SiOx) or silicon oxynitride (SiOxNy).

An impurity-doped polysilicon layer 104 is deposited to a thickness of about 1000 Å on the gate dielectric layer 102 by, for example, performing a CVD (Chemical Vapor Deposition) process on the gate dielectric layer 102.

Referring to FIG. 3B, an interface-reaction barrier layer 106 is formed to a thickness of about 50 Å on the polysilicon layer 104. The interface-reaction barrier layer 106 may be formed of a metal silicide, such as tungsten silicide (WSix).

Particularly, one method to form the interface-reaction barrier layer 106 includes initially forming a first metal layer, such as tungsten (W), to a thickness of about 50 Å on the polysilicon layer 104. The first metal layer can be formed by a sputtering process, or a CVD process, for example. Then, the first metal layer is heat-treated at a temperature of about 850° C. in ambient nitrogen (N₂) to cause the first metal layer to react with the polysilicon layer, thereby forming the metal silicide layer such as WSix for the barrier layer 106.

Alternatively, the metal silicide layer such as WSix can be directly deposited by a CVD or ALD (Atomic Layer Deposition) process using tungsten hexafluoride (WF6) and mono-silane (SiH4) gases under a pressure of about 200 mT, at a temperature of about 300˜400° C., preferably 360° C., thereby forming the interface-reaction preventing layer 106. In the case of using the ALD process, a tungsten (W) layer and a silicon (Si) layer are alternately chemisorbed to form a tungsten silicide (WSix) layer as the reaction preventing layer 106.

Referring to FIG. 3C, next a barrier layer 108 is formed. The barrier layer 108 can be formed of a metal-nitride layer, such as by depositing tungsten-nitride (WN) deposited to a thickness of about 100 Å on the interface-reaction preventing layer 106. The metal-nitride layer may be deposited by a sputtering process, a CVD process or an ALD process, for example. In a sputtering process, for example, the WN layer is deposited under a pressure of about 15 mT, a DC power of about 750 W, an N2 flow rate of 33 sccm, and at a temperature of about 150° C. Preferably, the WN layer has nitride content of about 40 atomic percent.

While the barrier layer 108 is being formed, the interface-reaction layer 106 prevents a formation of a high resistance SiN-based insulating layer that may be generated if the nitrogen (N2) from the metal-nitride barrier layer 108 were to react with the silicon of the polysilicon layer 104.

Referring to FIG. 3D, a metal layer 110, such as tungsten (W), is formed by depositing the metal layer on the barrier layer 108 to a thickness of about 500 Å by a sputtering process, a CVD process or an ALD process, for instance. For example, the tungsten (W) layer can be deposited by sputtering under a pressure of about 4 mT, a DC power of about 2 kW, and a temperature of about 150° C.

Preferably, forming the interface-reaction preventing layer 106, the barrier layer 108, and the metal layer 110 are performed in-situ, that is, in a single chamber without breaking the vacuum.

Next, silicon nitride is deposited on the metal layer 110 to form a gate capping layer 114. The gate capping layer 114 is formed to a thickness sufficient to prevent an oxidation of the metal layer 110 during any subsequent high temperature annealing processing.

After performing the above processes, the gate capping layer 114, the metal layer 110, the barrier layer 108, the interface-reaction preventing layer 106, and the polysilicon layer 104 are patterned by a photolithography process to form the metal-polysilicon gate stack (112 of FIG. 2).

Then, a selective oxidation may be performed at a temperature of about 850° C. in ambient H₂O/H₂ to thereby oxidize the vertical edge of the polysilicon layer 104 and the substrate 100. The selective oxidation is used to cure the etch damages in the substrate 100 and the gate dielectric layer 102, and to improve the gate-oxide integrity (GOI). During the selective oxidation, the interface-reaction preventing layer 106 such as WSix prevents the diffusion of oxidants towards the interface between the polysilicon layer 104 and the metal-nitride barrier layer 108, which would form a high resistance insulator.

Subsequent processes are continued to form source/drain regions (116 in FIG. 2), interconnections (not shown), etc.

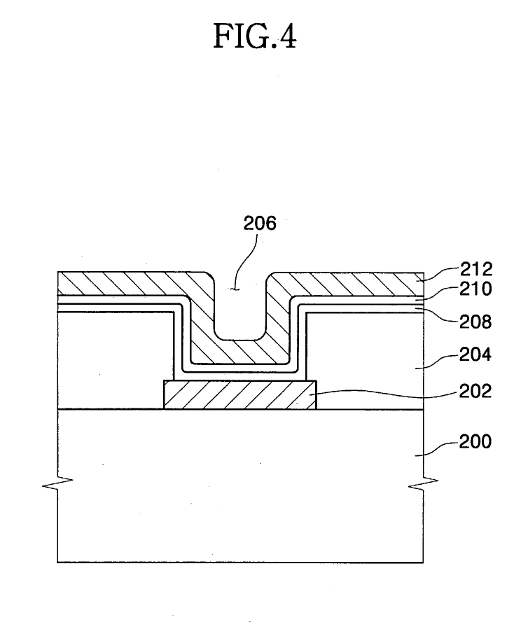

FIG. 4 is a cross-sectional view of a W-poly metal contact structure according to other embodiments of the present invention. Referring to FIG. 4, a polysilicon layer pattern 202 is formed on a substrate 200. In one example, a phosphorus doped polysilicon layer is deposited as a first metal interconnection layer to a thickness of about 1000 Å on the substrate 200 by a CVD-based process. Then the layer is patterned using a photoresist pattern as an etching mask to form the polysilicon layer pattern 202.

Next, a dielectric layer, such as a high-density plasma oxide layer, is deposited on the polysilicon layer pattern 202 and the substrate 200 to thereby form an inter-metal dielectric layer (IMD) 204. Through a photolithography process, the IMD layer 204 is selectively etched away to form a via hole 206, which exposes a portion of the polysilicon layer pattern 202. The via hole 206 can have, for example, a diameter of about 0.34 um.

Then, an interface-reaction barrier layer 208 of tungsten silicide (WSix) is formed to a thickness of about 30-50 Å. For example, the interface-reaction layer 208 can have a thickness of approximately 50 Å on the IMD layer 204 outside of the via hole 206, while having a thickness of only about 30 Å on the bottom surface of the via hole 206.

Forming a Wsix interface-reaction barrier layer 208 preferably begins by depositing a tungsten (W) layer to a suitable thickness by performing a sputtering process, a CVD process or an ALD process on the polysilicon layer pattern 202 and the substrate 200. Then, heat-treatment of the tungsten layer is performed for about 40 minutes at a temperature of approximately 850° C. in ambient nitrogen (N2) to cause the tungsten layer to react with silicon in the underlying polysilicon layer pattern 202. This reaction forms the tungsten silicide layer (WSix).

Alternatively, a tungsten silicide (WSix) layer may be deposited by performing a CVD or ALD process using tungsten hexafluoride (WF6) and mono-silane (SiH4) gases as source gases under a pressure of about 200 mT at a temperature of about 300˜400° C., and preferably at about 360° C.

Thereafter, a tungsten-nitride (WN) layer is deposited to a thickness of about 50-100 Å on the interface-reaction preventing layer 208 to form a barrier layer 210. The deposition of the WN barrier layer 210 can be carried out by sputtering, CVD, or ALD processes, for example. Preferably, the WN barrier layer 210 is deposited by performing a sputtering process under a pressure of about 15 mT, a DC power of about 750 W and a N2 flow rate of 33 sccm and at a temperature of about 150° C. Preferably, the WN barrier layer 210 has a content of nitride of about 40 atomic percent.

During the deposition of the WN barrier layer 210, the interface-reaction layer 208 prevents the formation of a high resistance SiN-based insulating layer which would occur if the nitrogen (N2) at the interface between the WN barrier layer 210 were to react with the exposed silicon in the polysilicon layer pattern 202.

Referring back to FIG. 4, next, as a second metal interconnection layer, such as a tungsten (W) layer 212 can be deposited to a thickness of about 300-500 Å on the WN barrier layer 210 by performing a sputtering, CVD or ALD process, thereby completing a W-poly contact structure. Preferably, the W layer 212 is deposited by performing a sputtering process under a pressure of about 4 mT, a DC power of about 2 kW, and at a temperature of about 150° C. Also, it is preferred that the processes of forming the interface-reaction preventing layer 208, the WN barrier layer 210, and the tungsten layer 212 all be performed in-situ.

Contact Resistance Measurement

To perform measurements of contact resistance, two W-poly contact structures were created and measured. A first structure was formed as described with reference to FIG. 4, and a second was formed the same as the first, with the exception of omitting the interface-reaction barrier layer 208. Contact resistances were measured with respect to the first and second structures.

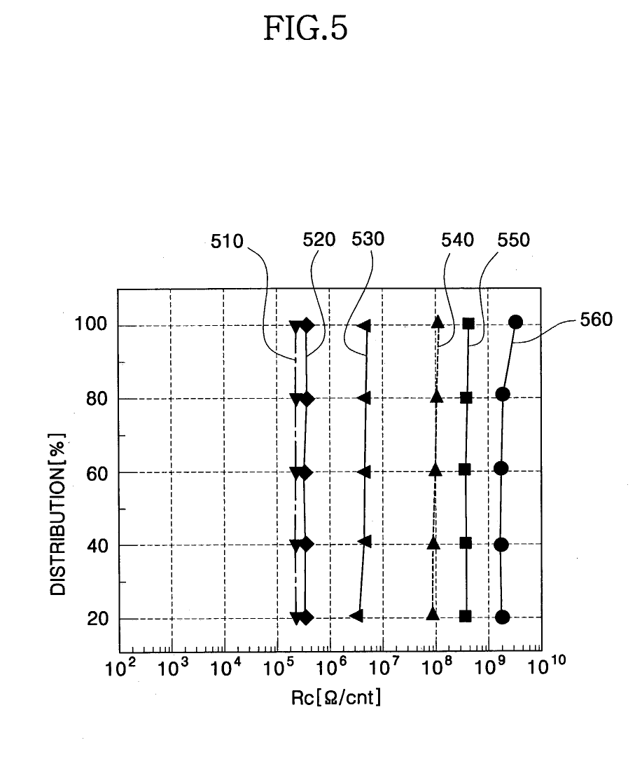

FIG. 5 is a graph showing contact resistances of the first and second W-poly contact structures. In the graph, the horizontal axis represents the observed contact resistance Rc (in Ω per each contact) and the vertical axis represents the Rc distribution. Six graph lines on the graph, numbered 510, 520, 530, 540, 550, and 560 illustrate the measured resistance for different contacts.

In the graph of FIG. 5, the graph lines 510, 520, and 530 (corresponding to symbols ●, &Rectversolid;, and ▴) illustrate the conventional W/WN/Poly contact structure. The graph line 520 shows the measured contact resistance of a contact formed where no annealing process was performed after the W layer was deposited. The graph line 530 shows the contact resistance of a contact having formed where the N2 annealing process was performed for no more than about 40 minutes at a temperature of about 850° C., after depositing the W layer. The graph line 510 shows the contact resistance for a contact formed including performing a selective oxidation at a temperature of 850° C. in a furnace, after the N2 annealing process.

The graph lines 540, 550, and 560 (corresponding to symbols ▾, ♦ and [symbol] ) illustrate measurements made from W/WN/WSix/Poly contact structures that conform to embodiments of the present invention in which the WSix layer was formed by depositing and heat-treating a tungsten layer. The graph line 540 shows the measured contact resistance for a contact formed with the N2 annealing process carried out for no more than about 40 minutes at a temperature of 850° C. after depositing the W layer. The graph line 550 shows the contact resistance for a contact formed with a selective oxidation performed by rapid thermal processing (RTP) at a temperature of 850° C. in a furnace after the N2 annealing process. The graph line 560 shows the contact resistance for a contact formed with a selective oxidation performed in a furnace at a temperature of 850° C. in a furnace, after the N2 annealing process.

Referring to FIG. 5, the graph line 520 shows that the contact resistance was measured at about 500MΩ/contact where no annealing process was performed to the conventional W/WN/Poly contact structure. When the N2 annealing was performed, as illustrated in the graph line 530, the contact resistance was reduced to about 100MΩ/contact. This reduction in resistance most likely occurs because a native oxide layer remaining on the surface of the polysilicon layer 104 (FIG. 2) or an amorphous layer created on the interface between the WN/Poly layers (104, 106 of FIG. 2) might have been partially removed by the N2 annealing process. Notably, when the selective oxidation in a furnace was performed, the contact resistance (as illustrated by graph line 510) increases to a few GΩ/contact. This occurs because oxidants generated from the oxidation diffuse into the interface between the WN/Poly layers (104, 106 of FIG. 2) and form an insulating layer, such as SiOx. Thus very little current can flow in the contact structure, due to the contact's high resistance.

On the contrary, the relatively low contact resistance (as shown by graph line 560) of about 200kΩ/contact was obtained when the contact was formed by performing an N₂ annealing to the W/WN/WSix/Poly contact structure (110, 108, 106, 104 of FIG. 2), because the WSix layer prevented the formation of an amorphous layer (or insulating layer) at the interface between the WN/Poly layers during the deposition of the WN layer. Similarly, when the RTP (Rapid Thermal Processing) selective oxidation was performed, the increase in the contact resistance (as shown by the graph line 550) was relatively insignificant. Interestingly, when the contract was formed with a selective oxidation process performed in a furnace, the contact resistance (as shown by the graph line 540) increased about 10 times to the contact having a resistance shown in the graph line 550 (RTP selective oxidation), but is still decreased about 30 times or more when compared to the resistance of the contact illustrated by the graph line 530 (conventional contact structure with a surface selective oxidation). This result occurs because the WSix layer (106 in FIG. 2) prevents the diffusion of oxidants to the interface between the WN/Poly layers (108, 104 in FIG. 2), thereby preventing the formation of an insulator such as SiOx.

According to metal-polysilicon stacks embodying the present invention, an interface-reaction preventing layer formed between a polysilicon layer and a metal-nitride barrier layer suppresses the formation of a high resistance amorphous (or insulation) layer during the metal-nitride layer deposition, and prevents the interface-reaction of oxidants during a subsequent selective oxidation process for curing etch damage. Therefore, the addition of the metal silicide layer between the metal-nitride layer and the polysilicon layer significantly reduces the contact resistance when compared to conventional contacts. Reduced contact resistance allows memory devices having a metal-polysilicon gate structure to be formed that satisfy present and future tRCD requirements.

Additionally, although the examples given herein illustrate the structure and sample processes of creating such a semiconductor structure, other processes and structures are possible while still staying within the scope of the present invention; for instance. Implementations having different processes and structures and other common variables in semiconductor devices are well within the scope of one skilled in the art, after being taught the principles of the invention disclosed above.

Those skilled in the art recognize that the different semiconductor devices described herein can be implemented in many different variations. Therefore, although various embodiments are specifically illustrated and described herein, it will be appreciated that modifications and variations of the present invention are covered by the above teachings and within the purview of the appending claims without departing from the spirit and intended scope of the invention.

1. A semiconductor device comprising:
a dielectric layer formed on a semiconductor substrate;
a polysilicon layer formed on the dielectric layer;
an interface-reaction preventing layer formed on the polysilicon layer, the interface-reaction preventing layer structured to prevent a reaction between the polysilicon layer and a material layer subsequently formed on the interface-reaction preventing layer;
a barrier layer formed on the interface-reaction preventing layer; and
a metal layer formed on the barrier layer.

2. The semiconductor device as claimed in claim 1 wherein the metal layer comprises tungsten.

3. The semiconductor device as claimed in claim 1 wherein the barrier layer comprises tungsten nitride.

4. The semiconductor device as claimed in claim 1 wherein the interface-reaction preventing layer comprises a metal-silicide.

5. A MOS transistor comprising:
a gate dielectric layer formed on a semiconductor substrate; and
a gate stack formed on the gate dielectric layer, the gate stack having a polysilicon layer disposed on the gate dielectric layer, an interface-reaction preventing layer disposed on the polysilicon layer, a tungsten nitride barrier layer disposed on the interface-reaction preventing layer, and a layer of tungsten disposed on the barrier layer.

6. The MOS transistor of claim 5 wherein the interface-reaction preventing layer comprises tungsten silicide.

7. The MOS transistor of claim 5, further comprising a gate capping layer disposed on the metal layer.

8. A method of manufacturing a semiconductor device, comprising:
forming a dielectric layer on a semiconductor substrate;
forming a polysilicon layer on the dielectric layer;
forming an interface-reaction preventing layer on the polysilicon layer;
forming a metal-nitride barrier layer on the interface-reaction preventing layer; and
forming a metal layer on the metal-nitride barrier layer, wherein forming the metal-nitride barrier layer does not comprise forming a titanium nitride layer.

9. The method of claim 8 wherein forming the metal layer comprises forming a tungsten layer.

10. The method of claim 8 wherein forming the metal-nitride barrier layer comprises forming a tungsten-nitride barrier layer.

11. The method of claim 8 wherein forming the interface-reaction preventing layer comprises forming a metal-silicide layer.

12. The method of claim 11 wherein forming the metal-silicide layer comprises:
depositing a first metal layer on the polysilicon layer; and
heat-treating the first metal layer to cause the first metal layer to react with the polysilicon layer.

13. The method of claim 12 wherein depositing the first metal layer comprises sputtering the first metal layer on the polysilicon layer.

14. The method of claim 12 wherein depositing the first metal layer comprises depositing the first metal layer on the polysilicon layer using chemical vapor deposition.

15. The method of claim 12 wherein depositing the first metal layer comprises depositing the first metal layer on the polysilicon layer using atomic layer deposition.

16. The method of claim 12 wherein heat-treating the first metal layer comprises heat-treating the first metal layer at a temperature of about 850° C. in ambient nitrogen.

17. The method of claim 11 wherein forming the metal-silicide layer comprises depositing the metal silicide layer on the polysilicon layer.

18. The method of claim 17 wherein depositing the metal silicide layer comprises sputtering the metal silicide layer on the polysilicon layer.

19. The method of claim 17 wherein depositing the metal silicide layer comprises depositing the metal silicide layer on the polysilicon layer using chemical vapor deposition.

20. The method of claim 17 wherein depositing the metal silicide layer comprises depositing the metal silicide layer on the polysilicon layer using atomic layer deposition.

21. The method of claim 8 wherein forming the interface-reaction preventing layer, forming the barrier layer and forming the metal layer are all performed in-situ.

22. A method of manufacturing a MOS transistor, comprising:
forming a gate dielectric layer on a semiconductor substrate;
forming a polysilicon layer on the dielectric layer;
forming an interface-reaction preventing layer on the polysilicon layer;
forming a tungsten-nitride barrier layer on the interface-reaction preventing layer; and
forming a tungsten layer on the barrier layer.

23. The method of claim 22, wherein forming the interface-reaction preventing layer comprises forming a tungsten silicide layer.

24. The method of claim 22, wherein forming the interface-reaction preventing layer comprises:
depositing a first tungsten layer on the polysilicon layer; and
heat-treating the first tungsten layer to cause the first tungsten layer to react with the polysilicon layer to form a tungsten silicide layer.

25. The method of claim 24, wherein depositing the first tungsten layer comprises sputtering the first tungsten layer, depositing the first tungsten layer by chemical vapor deposition, or by depositing the first tungsten layer by atomic layer deposition.

26. The method of claim 24 wherein heat-treating the first tungsten layer comprises heat-treating the first tungsten layer at a temperature of about 850° C. in ambient nitrogen.

27. The method of claim 22 wherein forming the interface-preventing layer comprises depositing a tungsten silicide layer.

28. The method of claim 27 wherein depositing the tungsten silicide layer comprises sputtering the tungsten silicide layer, depositing the tungsten silicide layer by chemical vapor deposition, or by depositing the tungsten silicide layer by atomic layer deposition.

29. The method of claim 18 wherein forming the interface-reaction preventing layer, forming the barrier layer and forming the tungsten layer are performed in-situ.

30. The method of claim 18, further comprising:
patterning the tungsten layer, the barrier layer, the interface-reaction preventing layer and the polysilicon layer to form a gate electrode; and
selectively oxidizing the gate electrode and the semiconductor substrate.

31. The method as claimed in claim 30, further comprising, before the patterning step, forming a gate capping layer on the tungsten layer.

32. A semiconductor device, comprising:
a substrate having a dielectric layer formed thereon;
a polysilicon layer disposed on the dielectric layer;
a metal layer formed over the polysilicon layer;
a barrier layer formed between the polysilicon layer and the metal layer; and
an additional layer formed between the polysilicon layer and the metal layer, the additional layer distinct from the barrier layer and structured to prevent chemical reactions when the barrier layer is formed.

33. The semiconductor device of claim 32 wherein the additional layer is also structured to prevent oxidants from diffusing to an interface between the barrier layer and the polysilicon layer.

34. The semiconductor device of claim 32 wherein one of the chemical reactions is formation of a relatively high resistance layer.

35. The semiconductor device of claim 32 wherein the additional layer is a tungsten silicide layer formed between the polysilicon layer and the barrier layer.

36. The semiconductor device of claim 35 wherein the barrier layer is a tungsten nitride layer formed on the tungsten silicide layer.

37. The semiconductor device of claim 35 wherein the metal layer is a tungsten layer.

38. The semiconductor device of claim 35, further comprising a silicon nitride layer formed over the tungsten layer.

39. A method for forming a semiconductor device, comprising:
forming a dielectric layer on a semiconductor substrate;
forming a polysilicon layer disposed on the dielectric layer;
forming a tungsten silicide layer on the polysilicon layer;
depositing a tungsten nitride layer on the tungsten silicide layer; and
depositing a tungsten layer on the tungsten nitride layer;

40. The method of claim 39, wherein forming the tungsten silicide layer comprises depositing the tungsten silicide layer.

41. The method of claim 39 wherein forming the tungsten silicide layer comprises:
forming a tungsten layer on the polysilicon layer; and
converting the tungsten layer on the polysilicon layer to the tungsten silicide layer.

42. The method of claim 41 wherein converting the tungsten layer on the polysilicon layer to the tungsten silicide layer comprises heat treating the tungsten layer on the polysilicon layer to form the tungsten silicide layer.

43. The method of claim 42 wherein heat treating comprises heat treating in a nitrogen atmosphere.

44. The method of claim 42 wherein heat treating comprises heat treating in a vacuum.

45. A semiconductor contact structure, comprising:
a polysilicon layer;
a dielectric layer disposed on the polysilicon layer;
a contact hole formed within the dielectric layer;
an interface reaction barrier disposed over the dielectric layer and in the contact hole, the interface reaction barrier adjacent the polysilicon layer within the contact hole;
a second barrier layer disposed on the interface reaction barrier; and
a second metal interconnection layer formed over the second barrier layer.

46. The semiconductor contact structure of claim 45 wherein the interface reaction layer substantially comprises tungsten silicide.

47. A method of forming a contact structure on a semiconductor substrate, comprising;
forming an interlayer dielectric layer having a contact hole therein, the contact hole open to a polysilicon layer formed on the substrate;
forming a interface-reaction preventing layer on the interlayer dielectric layer and within the contact hole, the interface-reaction preventing layer adjacent the polysilicon layer in the contact hole;
forming a barrier layer on the interface-reaction preventing barrier layer; and
forming an interconnection layer adjacent and on the barrier layer.

48. The method of claim 47 wherein forming the interlayer dielectric layer having a contact hole therein comprises:
forming an interlayer dielectric layer on the semiconductor substrate;
creating a contact hole within the interlayer dielectric layer; and
forming a polysilicon layer within the contact hole of the interlayer dielectric layer.

49. The method of claim 47 wherein forming the interlayer dielectric layer having a contact hole therein comprises:
forming the polysilicon layer on the semiconductor substrate;
patterning the polysilicon layer to form a polysilicon line;
forming an interlayer dielectric layer over the substrate and the polysilicon line; and
creating a contact hole within the interlayer dielectric layer at the point of the polysilicon line.
